(19) United States
(12) Patent Application Publication
(10) Pub. No.: US 2026/0215319 A1
(43) Pub. Date: Jul. 23, 2026

(54) SEMICONDUCTOR PACKAGE

(71) Applicant: SAMSUNG ELECTRONICS CO., LTD., Suwon-si (KR)

(72) Inventors: Gyuho KANG, Suwon-si (KR); Jisoo KIM, Suwon-si (KR); Hahyung PIN, Suwon-si (KR); Youngki CHO, Suwon-si (KR); Wonho CHOI, Suwon-si (KR); Hongseo HEO, Suwon-si (KR)

(73) Assignee: SAMSUNG ELECTRONICS CO., LTD., Suwon-si (KR)

(21) Appl. No.: 19/436,897

(22) Filed: Dec. 30, 2025

(30) Foreign Application Priority Data
Jan. 17, 2025 (KR) 10-2025-0007461

(51) Int. Cl. H10W 72/00; H10B 80/00; H10D 80/30; H10W 70/05; H10W 70/60; H10W 70/66; H10W 70/685; H10W 72/50; H10W 74/01; H10W 74/10; H10W 74/15; H10W 90/00; H10W 90/10; H10W 90/24

(52) U.S. Cl. CPC H10W 72/823; H10W 70/611; H10W 70/66; H10W 70/685; H10W 74/117; H10W 90/401; H10B 80/00; H10D 80/30; H10W 70/05; H10W 72/5453; H10W 74/016; H10W 74/15; H10W 90/10; H10W 90/24; H10W 90/724; H10W 90/752; H10W 90/754

(57) ABSTRACT

A semiconductor package may comprise: a first redistribution structure comprising first redistribution conductive patterns; a first semiconductor chip disposed on the first redistribution structure, and electrically connected to the first redistribution structure; a connection structure disposed on the first redistribution structure spaced apart from the first semiconductor chip in a horizontal direction, and electrically connected to the first redistribution structure; and a second redistribution structure disposed on the connection structure and comprising second redistribution conductive patterns, wherein the connection structure comprises: first conductive patterns comprising a first conductive material; and second conductive patterns comprising a second conductive material, different from the first conductive material, and alternately disposed with the first conductive patterns in a vertical direction intersecting the horizontal direction, and each of the second conductive patterns has a side surface protruding in the horizontal direction from a side surface of the respective first conductive pattern.

### CROSS-REFERENCE TO RELATED APPLICATION(S)

This application claims benefit of priority to Korean Patent Application No. 10-10-2025-0007461 filed on Jan. 17, 2025, in the Korean Intellectual Property Office, the disclosure of which is incorporated herein by reference in its entirety.

### BACKGROUND

The present inventive concept relates to a semiconductor package, and more specifically, to a semiconductor package including connection structures.

When manufacturing a semiconductor package, connection structures including copper (Cu) and a molded layer on side surfaces of the connection structures may be formed on a redistribution structure. An oxidation layer may be formed between the side surfaces of the connection structures and the molded layer, and the oxidation layer may cause a delamination phenomenon between the side surfaces of the connection structures and the molded layer, thereby resulting in a problem in which reliability of the semiconductor package is reduced.

### SUMMARY

An object of an aspect of the present inventive concept is to provide a semiconductor package with improved reliability.

However, objects of the present inventive concept are not limited to the mentioned object, and may be variously extended without departing from the spirit and scope of the present inventive concept.

According to an aspect of the present inventive concept, a semiconductor package may comprise: a first redistribution structure comprising first redistribution conductive patterns; a first semiconductor chip disposed on the first redistribution structure, and electrically connected to the first redistribution structure; a connection structure disposed on the first redistribution structure spaced apart from the first semiconductor chip in a horizontal direction, and electrically connected to the first redistribution structure; and a second redistribution structure disposed on the connection structure and comprising second redistribution conductive patterns, wherein the connection structure comprises: first conductive patterns comprising a first conductive material; and second conductive patterns comprising a second conductive material, different from the first conductive material, and alternately disposed with the first conductive patterns in a vertical direction intersecting the horizontal direction, and each of the second conductive patterns has a side surface protruding in the horizontal direction from a side surface of the respective first conductive pattern.

According to an aspect of the present inventive concept, a semiconductor package may comprise: a first redistribution structure comprising first redistribution conductive patterns; a connection structure disposed on the first redistribution structure, and electrically connected to the first redistribution structure; a first molded layer disposed on a side surface of the connection structure; and a second redistribution structure disposed on the connection structure and the first molded layer, and comprising second redistribution conductive patterns, wherein the connection structure comprises a plurality of conductive pattern structures stacked in a vertical direction, and each of the plurality of conductive patterns comprises: a first conductive pattern comprising a first conductive material; and a second conductive pattern disposed on the first conductive pattern, and comprising a second conductive material, different from the first conductive material, and each of the first conductive patterns has a side surface disposed inwardly of a side surface of the respective second conductive pattern.

According to an aspect of the present inventive concept, a semiconductor package may comprise: a lower package; conductive bumps disposed on the lower package; and an upper package disposed on the conductive bumps, wherein the lower package comprises: a first redistribution structure comprising first redistribution conductive patterns, and having a lower surface on which lower pads connected to the first redistribution conductive patterns are disposed; lower pads disposed on the lower surface of the first redistribution structure; lower connection bumps disposed below the lower pads; a first semiconductor chip disposed on the first redistribution structure, and electrically connected to the first redistribution structure; a connection structure disposed on the first redistribution structure spaced apart from the first semiconductor chip in a horizontal direction, and electrically connected to the first redistribution structure; and a second redistribution structure disposed on the connection structure, and comprising second redistribution conductive patterns, and the connection structure comprises: first conductive patterns comprising a first conductive material; and second conductive patterns comprising a second conductive material, different from the first conductive material, and alternately disposed with the first conductive patterns in a vertical direction intersecting the horizontal direction, and each of the second conductive patterns has a side surface protruding in the horizontal direction from a side surface of the respective first conductive pattern.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a cross-sectional view of a semiconductor package according to an embodiment of the present inventive concept;

FIG. 2A is an enlarged view of a region “A” of the semiconductor package illustrated in FIG. 1, according to an embodiment;

FIGS. 2B and 2C are enlarged views of the region “A” of the semiconductor package illustrated in FIG. 1, according to other embodiments;

FIG. 3 is a cross-sectional view of a semiconductor package according to another embodiment of the present inventive concept;

FIG. 4 is a cross-sectional view of a semiconductor package according to another embodiment of the present inventive concept; and

FIGS. 5A, 5B, 5C, 5D, 5E, 5F, 5G, 5H and 5I are drawings illustrating cross-sections of intermediate semiconductor package during a method of manufacturing a semiconductor package according to an embodiment of the present inventive concept.

### DETAILED DESCRIPTION

Hereinafter, example embodiments of the present inventive concept will be described with reference to the accompanying drawings. The same reference numerals are used for the same components in the drawings, and duplicate descriptions for the same components are omitted.

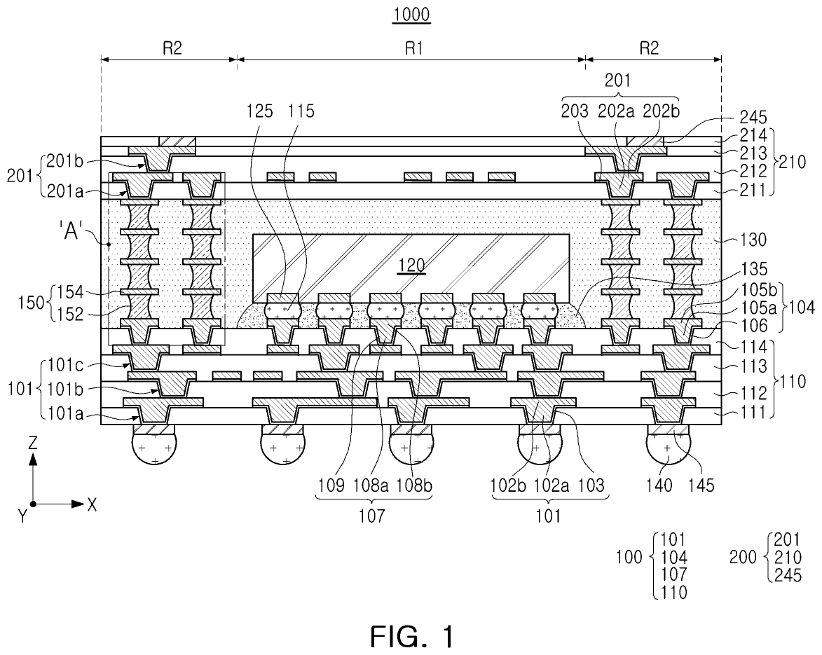

FIG. 1 is a cross-sectional view of a semiconductor package according to an embodiment of the present inventive concept.

Referring to FIG. 1, the semiconductor package 1000 may include a first redistribution structure 100, a second redistribution structure 200, a first semiconductor chip 120 disposed on the first redistribution structure 100, and connection structures 150 disposed between the first redistribution structure 100 and the second redistribution structure 200.

The semiconductor package 1000 may further include lower pads 145 disposed on a lower surface of the first redistribution structure 100, and lower connection bumps 140 disposed on lower surfaces of the lower pads 145 and electrically connected to the lower pads 145.

The semiconductor package 1000 may be a semiconductor package having a fan-out structure, and some of the lower connection bumps 140 of the semiconductor package 1000 may be disposed at positions spaced outward from a side surface of the first semiconductor chip 120. The lower connection bumps 140 may include tin (Sn) or an alloy containing tin (Sn) (e.g., Sn—Ag—Cu).

The first redistribution structure 100 may be a front redistribution layer of the semiconductor package 1000. The first redistribution structure 100 may be a support substrate on which the first semiconductor chip 120 is mounted, and may include at least two interconnection layers stacked with each other.

The first redistribution structure 100 may include first redistribution insulating layers 110, first redistribution conductive patterns 101 in the first redistribution insulating layers 110, first connection patterns 104, and second connection patterns 107.

The first redistribution structure 100 may include a first region R1, and a second region R2 adjacent to the first region R1. The first region R1 of the first redistribution structure 100 may be a region in which the first semiconductor chip 120 is disposed, and the second region R2 of the first redistribution structure 100 may be a region in which the connection structures 150 are disposed. In an example, the second region R2 may surround the first region R1. However, the present inventive step is not limited thereto, and in another example, the second region R2 may be disposed on one side of the first region R1.

The first redistribution conductive patterns 101 may be disposed in the first redistribution insulating layers 110, and may include (1-1)-th redistribution conductive patterns 101a, (1-2)-th redistribution conductive patterns 101b disposed on the (1-1)-th redistribution conductive patterns 101a, and (1-3)-th redistribution conductive patterns 101c on the (1-2)-th redistribution conductive patterns 101b. The number of the first redistribution conductive patterns 101 is not limited to three illustrated in FIG. 1, and may be two or less or four or more.

Each of the first redistribution conductive patterns 101 may include a first redistribution via 102a, a first redistribution line 102b on the first redistribution via 102a, and a first seed layer 103 disposed on a lower surface and a side surface of the first redistribution via 102a and a lower surface of the first redistribution line 102b. The first redistribution line 102b may be an interconnection extending from the first redistribution via 102a on the first redistribution via 102a and extending in one direction (e.g., in a second direction (Y-direction)). The first redistribution via 102a and the first redistribution line 102b may be formed integrally. Each of the first redistribution vias 102a may be a filled via in which a metal material is filled inside a via hole or a conformal via in which a metal material is formed along an inner wall of the via hole.

The first redistribution via 102a and the first redistribution line 102b may include a conductive material. For example, the first redistribution via 102a and the first redistribution line 102b may include copper (Cu) or aluminum (Al). The first seed layer 103 may include copper (Cu), Aluminum (Al), silver (Ag), tin (Sn), gold (Au), nickel (Ni), lead (Pb), titanium (Ti), or an alloy thereof. In an example embodiment, the first seed layer 103 may include titanium (Ti), copper (Cu), or an alloy thereof.

The first redistribution via 102a of the (1-1)-th redistribution conductive pattern 101a may be disposed between the first redistribution line 102b of the (1-1)-th redistribution conductive pattern 101a and the lower pad 145. The first redistribution via 102a of the (1-2)-th redistribution conductive pattern 101b may be disposed between the first redistribution line 102b of the (1-1)-th redistribution conductive pattern 101a and the first redistribution line 102b of the (1-2)-th redistribution conductive pattern 101b to electrically connect the first redistribution lines 102b. The first redistribution via 102a of the (1-3)-th redistribution conductive pattern 101c may be disposed between the first redistribution line 102b of the (1-2)-th redistribution conductive pattern 101b and the first redistribution line 102b of the (1-3)-th redistribution conductive pattern 101c to electrically connect the first redistribution lines 102b.

The first redistribution insulating layers 110 may include a (1-1)-th redistribution insulating layer 111, a (1-2)-th redistribution insulating layer 112, a (1-3)-th redistribution insulating layer 113, and a (1-4)-th redistribution insulating layer 114, which are sequentially stacked in a vertical direction (Z-direction). In an example, the (1-1)-th redistribution insulating layer 111 may be disposed on a side surface of the first redistribution via 102a of the (1-1)-th redistribution conductive pattern 101a. The (1-2)-th redistribution insulating layer 112 may be disposed on the (1-1)-th redistribution insulating layer 111, may cover the first redistribution line 102b of the (1-1)-th redistribution conductive pattern 101a, and may be disposed on a side surface of the first redistribution via 102a of the (1-2)-th redistribution conductive pattern 101b. The (1-3)-th redistribution insulating layer 113 may be disposed on the (1-2)-th redistribution insulating layer 112, may cover the first redistribution line 102b of the (1-2)-th redistribution conductive pattern 101b, and may be disposed on a side surface of the first redistribution via 102a of the (1-3)-th redistribution conductive pattern 101c. The (1-4)-th redistribution insulating layers 114 may be disposed on side surfaces of first connection vias 105a of the first connection patterns 104 and side surfaces of second connection vias 108a of the second connection patterns 107, as will be describe blow.

The first redistribution insulating layers 110 may include an insulating polymer or a photosensitive insulating material (PID, photo-imageable dielectric). For example, the photosensitive insulating material may include at least one of a photosensitive polyimide (PI), a polybenzoxazole (PBO), a phenol-based polymer, or a benzocyclobutene-based polymer. Alternatively, the first redistribution insulating layers 110 may include an insulating material. For example, the first redistribution insulating layer 110 may include silicon oxide (SiO), silicon nitride (SiN), silicon oxynitride (SiON), silicon carbon nitride (SiCN), or an insulating polymer. In an example, a boundary between the first redistribution insulating layers 110 may be unclear depending on the manufacturing process.

The first connection patterns 104 may be disposed on the (1-3)-th redistribution conductive patterns 101c. The connection structures 150 may be electrically connected to the first redistribution conductive patterns 101 through the first connection patterns 104. The first connection patterns 104 may overlap the second region R2. Each of the first connection patterns 104 may include a first connection via 105a, a first connection pad 105b extending from the first connection via 105a to be disposed on the (1-4)-th redistribution insulating layer 114, and a first connection seed layer 106 disposed on a lower surface and a side surface of the first connection via 105a and a lower surface of the first connection pad 105b. The first connection pad 105b may be a pad on which connection structures 150 are disposed.

The second connection patterns 107 may be disposed on the (1-3)-th redistribution conductive patterns 101c, and the first semiconductor chip 120 may be electrically connected to the first redistribution conductive patterns 101 through the second connection patterns 107. The second connection patterns 107 may overlap the first region R1. Each of the second connection patterns 107 may include a second connection via 108a, a second connection pad 108b extending from the second connection via 108a to be disposed on the (1-4)-th redistribution insulating layer 114, and a second connection seed layer 109 disposed on a lower surface and a side surface of the second connection via 108a and on a lower surface of the second connection pad 108b. Intermediate connection bumps 115 may be disposed on the second connection pads 108b.

The first semiconductor chip 120 may be disposed on the second connection pads 108b of the second connection patterns 107. Intermediate connection pads 125 may be disposed on a lower surface of the first semiconductor chip 120. The intermediate connection bumps 115 may be disposed between the intermediate connection pads 125 and the second connection pads 108b. The first semiconductor chip 120 may be electrically connected to the first redistribution structure 100 through intermediate connection pads 125, the intermediate connection bumps 115, and the second connection patterns 107.

The intermediate connecting pads 125 and the lower pads 145 may include a metal material. The metal material may include at least one metal or an alloy including two or more metals of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or carbon (C).

The intermediate connection bumps 115 may include a low melting point metal, such as tin (Sn) or an alloy including tin (Sn). In some embodiments, the intermediate connection bumps 115 may have a structure in which a metal pillar and a solder ball are combined.

The semiconductor package 1000 may further include a first underfill material layer 135 surrounding the intermediate connection bumps 115 disposed between the first semiconductor chip 120 and the first redistribution structure 100. The first underfill material layer 135 may have a capillary underfill (CUF) structure. However, the present inventive concept is not limited thereto, and the first underfill material layer 135 may have a molded underfill (MUF) structure integrated with a first molded layer 130, which will be described below.

The first semiconductor chip 120 may include an integrated circuit (IC) and a semiconductor wafer made of a semiconductor element such as silicon, germanium, or a compound semiconductor such as silicon carbide (SiC), gallium arsenide (GaAs), indium arsenide (InAs), and indium phosphide (InP). The first semiconductor chip 120 may be a bare semiconductor chip without a separate bump or interconnection layer formed thereon. However, the present inventive concept is not limited thereto, and the first semiconductor chip 120 may also be a packaged type semiconductor chip.

The first semiconductor chip 120 may include a logic circuit (or “logic chip”) such as a central processor (CPU), a graphic processor (GPU), a field programmable gate array (FPGA), an application processor (AP), a digital signal processor, an encryption processor, a microprocessor, a microcontroller, an analog-to-digital converter, and an application-specific IC (ASIC), or a memory circuit (or “memory chip”) including a volatile memory such as a dynamic RAM (DRAM) and a static RAM (SRAM), and a nonvolatile memory such as a phase change RAM (PRAM), a magnetic RAM (MRAM), a resistive RAM (RRAM) and a flash memory.

The connection structures 150 may be disposed on the first connection patterns 104. The connection structures 150 may be disposed around the first semiconductor chip 120, and may be spaced apart from the first semiconductor chip 120 in a horizontal direction. In an example, the connection structures 150 may overlap the second region R2 of the first redistribution structure 100. Each of the connection structures 150 may include first conductive patterns 152 and second conductive patterns 154 alternately disposed with the first conductive patterns 152 in the vertical direction (Z-direction).

In an example, the first conductive pattern 152 may include a first conductive material, and the second conductive pattern 154 may include a second conductive material, different from the first conductive material. In an example, the first conductive pattern 152 may include a material whose oxidation rate is faster than that of the second conductive pattern 154 in a process of manufacturing the semiconductor package 1000. For example, the first conductive pattern 152 may include copper (Cu), and the second conductive pattern 154 may include nickel (Ni).

As the first conductive patterns 152 and the second conductive patterns 154 are alternately disposed in the vertical direction (Z-direction), the second conductive pattern 154 may be disposed between two first conductive patterns 152 that are spaced apart in the [symbol] . In an example, the first conductive pattern 152 disposed on a lowermost end of the first conductive patterns 152 may be in contact with an upper surface of the first connection pad 105b of the first connection patterns 104. In an example, the second conductive pattern 154 disposed on an uppermost end of the second conductive patterns 154 may be in contact with a lower surface of the second redistribution structure 200.

In an embodiment, heights of the first conductive patterns 152 in the vertical direction (Z-direction) may be the same as each other, and may be greater than heights of the respective second conductive patterns 154 in the vertical direction (Z-direction).

In an embodiment, a side surface (or side wall) of each of the first conductive patterns 152 may be disposed inwardly of a side surface (or side wall) of each of the second conductive patterns 154.

The first molded layer 130 may be disposed on the first redistribution structure 100, may cover the side surface and an upper surface of the first semiconductor chip 120 on the first redistribution structure 100, and may be disposed on a side surface of each of the connection structures 150. In an example, the first molded layer 130 may be disposed on an upper surface of the (1-4)-th redistribution insulating layer 114, and may cover portions of upper surfaces and side surfaces of the first connection pads 105b of the first connection patterns 104.

The first molded layer 130 may be in contact with side surfaces of the first conductive patterns 152 and side surfaces of the second conductive patterns 154 of each of the connection structures 150. In an example, the first molded layer 130 may include, for example, a thermosetting resin such as an epoxy resin, a thermoplastic resin such as a polyimide, or a prepreg, ABF, FR-4, BT, EMC (Epoxy Molding Compound), etc.

An upper surface of the first molded layer 130 may be coplanar with the upper surface of each of the connection structures 150, and may be disposed on a level higher than the upper surface of the first semiconductor chip 120.

The second redistribution structure 200 may be disposed on the connection structures 150 and the first molded layer 130. In an example, the second redistribution structure 200 may be a backside redistribution layer of the semiconductor package 1000.

The second redistribution structure 200 may include second redistribution insulating layers 210, second redistribution conductive patterns 201 in the second redistribution insulating layers 210, and upper pads 245.

The second redistribution conductive patterns 201 may be disposed in the second redistribution insulating layers 210, and may include (2-1)-th redistribution conductive patterns 201a and (2-2)-th redistribution conductive patterns 201b disposed on the (2-1)-th redistribution conductive patterns 201a. The number of second redistribution conductive patterns 201 is not limited to two as illustrated in FIG. 1, and may be three or more.

Each of the second redistribution conductive patterns 201 may include a second redistribution via 202a, a second redistribution line 202b on the second redistribution via 202a, and a second seed layer 203 disposed on a lower surface and a side surface of the second redistribution via 202a and a lower surface of the second redistribution line 202b. The second redistribution line 202b may be an interconnection extending from the second redistribution via 202a on the second redistribution via 202a in one direction (e.g., the second direction (Y-direction)). The second redistribution via 202a and the second redistribution line 202b may be formed integrally. Each of the second redistribution vias 202a may be a filled via in which a metal material is filled in a via hole or a conformal via in which a metal material is formed along an inner wall of the via hole.

The second redistribution via 202a and the second redistribution line 202b may include a conductive material. For example, the second redistribution via 202a and the second redistribution line 202b may include copper (Cu) or aluminum (Al). The second seed layer 203 may include copper (Cu), aluminum (Al), silver (Ag), tin (Sn), gold (Au), nickel (Ni), lead (Pb), titanium (Ti), or an alloy thereof. In an example embodiment, the second seed layer 203 may include titanium (Ti), copper (Cu), or an alloy thereof.

In an example, the second redistribution vias 202a of the (2-1)-th redistribution conductive patterns 201a may be disposed between the connection structures 150 and the second redistribution lines 202b of the (2-1)-th redistribution conductive patterns 201a. In an example, the second redistribution vias 202a of the (2-1)-th redistribution conductive patterns 201a may be in contact with an upper surface of the second redistribution conductive pattern 154 disposed on an uppermost end of the second redistribution conductive patterns 154. The second redistribution vias 202a of the (2-2)-th redistribution conductive patterns 201b may be disposed between the second redistribution lines 202b to electrically connect the second redistribution lines 202b.

The second redistribution insulating layers 210 may include a (2-1)-th redistribution insulating layer 211, a (2-2)-th redistribution insulating layer 212, a (2-3)-th redistribution insulating layer 213, and a (2-4)-th redistribution insulating layer 214, which are sequentially stacked in the vertical direction (Z-direction).

The (2-1)-th redistribution insulating layer 211 may be in contact with upper surfaces of the connection structures 150 and the first molded layer 130, and may surround side surfaces of the second redistribution vias 202a of the (2-1)-th redistribution conductive patterns 201a. The (2-2)-th redistribution insulating layer 212 may be disposed on the (2-1)-th redistribution insulating layer 211, may cover the second redistribution lines 202b of the (2-1)-th redistribution conductive patterns 201a, and may surround the second redistribution vias 202a of the (2-2)-th redistribution conductive patterns 201b. The second redistribution lines 202b of the (2-1)-th redistribution conductive patterns 201a may extend from the second redistribution vias 202a of the (2-1)-th redistribution conductive patterns 201a, and may be disposed on the (2-1)-th redistribution insulating layer 211. The (2-3) redistribution insulating layer 213 may be disposed on a side surface of the second redistribution lines 202b of the (2-2)-th redistribution conductive patterns 201b. The (2-4) redistribution insulating layer 214 may be disposed on the (2-3) redistribution insulating layer 213, and may surround the upper pads 245 disposed on the (2-2)-th redistribution conductive patterns 201b.

The semiconductor package 1000 according to embodiments of the present inventive concept may include the connection structures 150 disposed between the first redistribution structure 100 and the second redistribution structure 200, each of which may include the first conductive patterns 152 and the second conductive patterns 154 alternately disposed with the first conductive patterns 152 in the vertical direction (Z-direction), and each of the second conductive patterns 154 may have a side surface protruding in a horizontal direction from a side surface of each of the first conductive patterns 152. Accordingly, since an oxidation rate of the second conductive pattern 154 may be less than an oxidation rate of the first conductive pattern 152, an oxidation layer formed between each of the connection structures 150 and the first molded layer 130 may be reduced. In addition, an oxidation layer formed between a side surface of the first conductive pattern 152 and the first molded layer 130 may be prevented from spreading upward and downward through the second conductive pattern 154 having a protruding side surface. Therefore, a delamination of the side surface of each of the connection structures 150 from the first molded layer 130 due to the formation of the oxidation layer between the side surface of each of the connection structures 150 and the first molded layer 130 may be minimized or improved, thereby providing a semiconductor package with improved reliability.

Herein, a first direction (X-direction) and a second direction (Y-direction) may be perpendicular to each other. The first direction (X-direction) and the second direction (Y-direction) may be perpendicular to a third direction (Z-direction). A horizontal direction may refer to the first direction (X-direction) or the second direction (Y-direction), and a vertical direction may refer to the third direction (Z-direction).

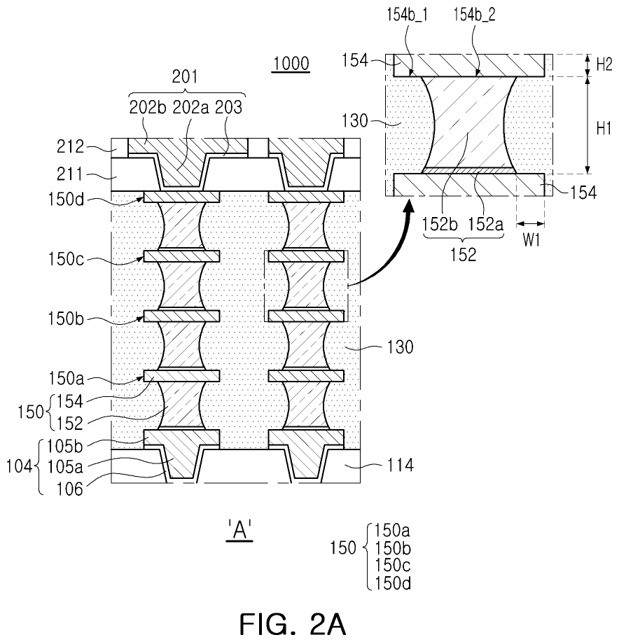

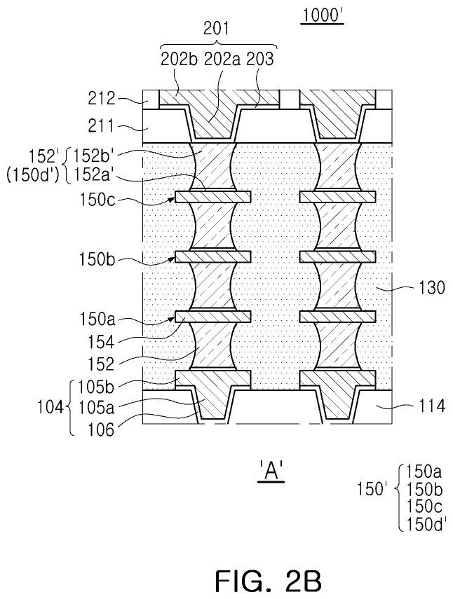

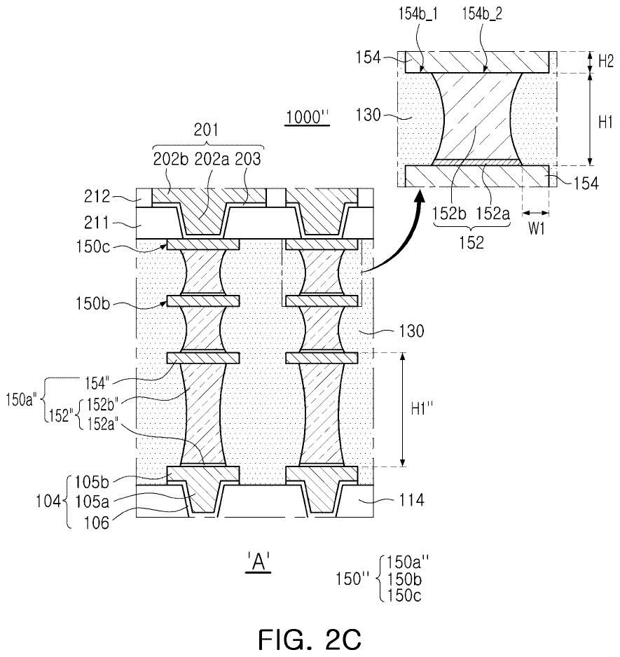

FIG. 2A is an enlarged view of a region “A” of the semiconductor package illustrated in FIG. 1, according to an embodiment.

Referring to FIG. 1 and FIG. 2A, the connection structures 150 may include a plurality of conductive pattern structures 150a, 150b, 150c and 150d stacked in the vertical direction (Z-direction). The plurality of conductive pattern structures 150a, 150b, 150c and 150d may include a first conductive pattern structure 150a, a second conductive pattern structure 150b, a third conductive pattern structure 150c, and a fourth conductive pattern structure 150d, which are sequentially stacked in the vertical direction (Z-direction). The number of the plurality of conductive pattern structures 150a, 150b, 150c and 150d is not limited to four illustrated in FIG. 1, and may be three or less or five or more.

The first conductive pattern 152 may include a first conductive material, and the second conductive pattern 154 may include a second conductive material, different from the first conductive material. In an example, the first conductive pattern 152 may include a first metal layer 152a and a second metal layer 152b on the first metal layer 152a. The first metal layer 152a may be a seed layer for the second metal layer 152b. The second conductive pattern 154 may include a third metal layer. The second metal layer 152b of the first conductive pattern 152 may have an electro potential higher than that of the third metal layer. The higher electro potential may mean that it has a relatively positive value. For example, the first metal layer 152a may include titanium (Ti), and the second metal layer 152b may include copper (Cu). The third metal layer may include nickel (Ni).

Each of the plurality of conductive pattern structures 150a, 150b, 150c and 150d may include the first conductive pattern 152 and the second conductive pattern 154 on the first conductive pattern 152. A first height H1 of the first conductive pattern 152 in the vertical direction (Z-direction) may be greater than a second height H2 of the second conductive pattern 154 in the vertical direction (Z-direction). For example, the first height H1 may be about 3 to about 4 times of the second height H2. In an example, the second height H2 of the second conductive pattern 154 may be about 3 μm or less, and the first height H1 of the first conductive pattern 152 may be about 9 μm to about 12 μm.

A side surface of the first conductive pattern 152 may be disposed inwardly of a side surface of the second conductive pattern 154. In an example, the side surface of the second conductive pattern 154 may protrude from the side surface of the first conductive pattern 152 in the horizontal direction. For example, the side surface of the second conductive pattern 154 may protrude from the side surface of the first conductive pattern 152 by about a first width (W1) in the horizontal direction. The first width (W1) may be about 200 nm or more and about 300 nm or less.

In an embodiment, the side surface of the first conductive pattern 152 may have a concave curved surface. That is, the side surface of the first conductive pattern 152 may have a side surface recessed inwardly toward the first conductive pattern 152. A maximum width in the horizontal direction of the first conductive pattern 152 may be less than a maximum width in the horizontal direction of the second conductive pattern 154.

In an embodiment, a lower surface of the second conductive pattern 154 may include an overlapping region 154b_2 which overlaps the first conductive pattern 152 in the vertical direction (Z-direction) and a non-overlapping region 154b_1 which is exposed from the first conductive pattern 152. In an example, the overlapping region 154b_2 may be in contact with the second metal layer 152b of the first conductive pattern 152. In an example, the non-overlapping region 154b_1 may be a region which does not overlap the first conductive pattern 152 in the vertical direction (Z-direction), and may be in contact with the first molded layer 130.

In an example, an upper surface of the second conductive pattern 154 may be in contact with the first conductive pattern 152 of another conductive pattern structure, in which case the upper surface of the second conductive pattern 154 may include the overlapping region 154b_2 and the non-overlapping region 154b_1 in the same manner as the lower surface of the second conductive pattern 154. For example, the upper surface of the second conductive pattern 154 of the first conductive pattern structure 150a may be in contact with the first conductive pattern 152 of the second conductive pattern structure 150b, and the lower surface of the second conductive pattern 154 of the first conductive pattern structure 150a may be in contact with the first conductive pattern 152 of the first conductive pattern structure 150a. In this case, the overlapping region 154b_2 of the upper surface of the second conductive pattern 154 of the first conductive pattern structure 150a may be in contact with the first metal layer 152a of the first conductive pattern 152 of the second conductive pattern structure 150b.

The first conductive pattern structure 150a disposed on a lowermost end of the plurality of conductive pattern structures 150a, 150b, 150c and 150d may be in contact with an upper surface of the first redistribution structure 100. In an example, a lower surface of the first conductive pattern 152 of the first conductive pattern structure 150a may be in contact with the upper surface of the first connection patterns 104. Herein, the first conductive pattern 152 of the first conductive pattern structure 150a may be referred to as a “first lower conductive pattern,” and the second conductive pattern 154 of the first conductive pattern structure 150a may be referred to as a “second lower conductive pattern.”

The fourth conductive pattern structure 150d disposed on an uppermost end of the plurality of conductive pattern structures 150a, 150b, 150c and 150d may be in contact with the lower surface of the second redistribution structure 200. In an example, the upper surface of the second conductive pattern 154 of the fourth conductive pattern structure 150d may be in contact with a lower surface of the second redistribution via 202a of the second redistribution conductive pattern 201. Herein, the first conductive pattern 152 of the fourth conductive pattern structure 150d may be referred to as a “first upper conductive pattern,” and the second conductive pattern 154 of the fourth conductive pattern structure 150d may be referred to as a “second upper conductive pattern.”

FIGS. 2B and 2C are enlarged views of the region “A” region of a semiconductor package illustrated in FIG. 1, according to other embodiments.

Referring to FIG. 2B, a semiconductor package 1000′may include connection structures 150′. The connection structures 150′may include a plurality of conductive pattern structures 150a, 150b, 150c and 150d'. The plurality of conductive pattern structures 150a, 150b, 150c and 150d′ may include a first conductive pattern structure 150a, a second conductive pattern structure 150b, a third conductive pattern structure 150c, and a fourth conductive pattern structure 150d', which are sequentially stacked in the vertical direction (Z-direction). The first conductive pattern structure 150a, the second conductive pattern structure 150b, and the third conductive pattern structure 150c of the connection structure 150′may correspond to the first conductive pattern structure 150a, the second conductive pattern structure 150b, and the third conductive pattern structure 150c of the connection structure 150 of FIG. 2A.

The fourth conductive pattern structure 150d′ may be a conductive pattern structure disposed on an uppermost end of the plurality of conductive pattern structures 150a, 150b, 150c and 150d′, and may be in contact with the second redistribution conductive patterns 201. The fourth conductive pattern structure 150d′ may include a first conductive pattern 152′. An upper surface of the first conductive pattern 152′ of the fourth conductive pattern structure 150d′ may be exposed from the first molded layer 130, and may be in contact with the second redistribution conductive patterns 201. The first conductive pattern 152′ may correspond to the first conductive pattern 152 of the first to third conductive pattern structures 150a, 150b and 150c. The first conductive pattern 152′ may include a first metal layer 152a′ and a second metal layer 152b′ on the first metal layer 152a′. The second metal layer 152b′ may be a seed layer of the first metal layer 152a′. Herein, the first conductive pattern 152′ may be referred to as a first upper conductive pattern.

Referring to FIG. 2C, a semiconductor package 1000″ may include connection structures 150″. The connection structures 150″ may include a plurality of conductive pattern structures 150a″, 150b and 150c. The plurality of conductive pattern structures 150a″, 150b and 150c may include a first conductive pattern structure 150a″, a second conductive pattern structure 150b, and a third conductive pattern structure 150c, which are sequentially stacked in the vertical direction (Z-direction). The first conductive pattern structure 150a″ may include a first conductive pattern 152″ and a second conductive pattern 154″ on the first conductive pattern 152″. Each of the second conductive pattern structure 150b and the third conductive pattern structure 150c may include a first conductive pattern 152 and a second conductive pattern 154 on the first conductive pattern 152.

A third height H1″ of the first conductive pattern 152″ of the first conductive pattern structure 150a″ in the vertical direction (Z-direction) may be greater than the first height H1 of the first conductive pattern 152 of each of the second conductive pattern structure 150b and the third conductive pattern structure 150c in the vertical direction (Z-direction). Since the first conductive pattern 152 of the third conductive pattern structure 150c of the connection structures 150″ is disposed on an uppermost end of the first conductive patterns 152 and 152″ constituting the connection structures 150″, it may be referred to as a “first uppermost conductive pattern” herein. In an example, the number of the plurality of conductive pattern structures 150a″, 150b and 150c may be three, but is not limited thereto, and may be four or more.

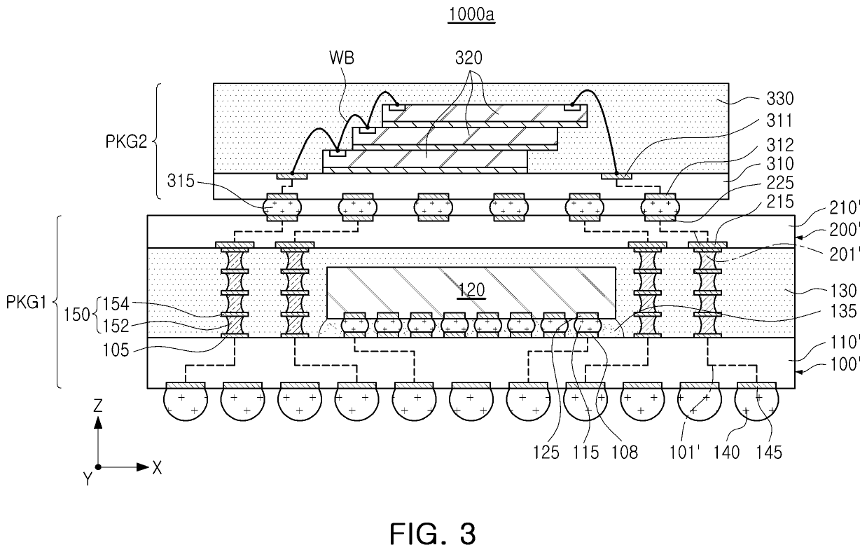

FIG. 3 is a cross-sectional view of a semiconductor package according to another embodiment of the present inventive concept.

Referring to FIG. 3, the semiconductor package 1000a may include a first semiconductor structure, e.g., a lower package PKG1 and second semiconductor structure, e.g., an upper package PKG2 disposed on the lower package PKG1.

The lower package PKG1 may include a lower base 100′, an upper base 200′, connection structures 150 disposed between the lower base 100′ and the upper base 200′, and a first semiconductor chip 120.

The lower base 100′ may include a lower substrate 110′, lower pads 145, first upper pads 105 and 108, a first lower interconnection circuit 101′ electrically connecting the lower pads 145 and the first upper pads 105 and 108, and lower connection bumps 140.

The first upper pads 105 and 108 may include (1-1)-th upper pads 105 and (1-2)-th upper pads 108. The (1-1)-th upper pads 105 may be disposed on an upper surface of the lower substrate 110′, and connection structures 150 may be disposed thereon. Intermediate connection bumps 115 may be disposed on the (1-2)-th upper pads 108. The first semiconductor chip 120 may be disposed on the (1-2)-th upper pads 108, and electrically connected to the lower base 100′through the intermediate connection bumps 115.

The upper base 200′ may be spaced apart from the lower base 100′ in the vertical direction (Z-direction). The upper base 200′ may include an upper substrate 210′, second lower pads 215, second upper pads 225, and a second lower interconnection circuit 201′ electrically connecting the second lower pads 215 and the second upper pads 225.

The connection structures 150 may be disposed between the lower base 100′ and the upper base 200′ to electrically connect the lower base 100′ and the upper base 200′. The connection structure 150 of the semiconductor package 1000a may be applied with the connection structures 150, 150′ and 150″ described with reference to FIGS. 1 to 2C.

The upper package PKG2 may include an interconnection substrate 310, semiconductor chips 320, and an encapsulant 330. The interconnection substrate 310 may include a third upper pad 311 and a third lower pad 312. In addition, the interconnection substrate 310 may include an upper interconnection circuit 313 electrically connecting the third upper pad 311 and the third lower pad 312. The interconnection substrate 310 may be a semiconductor package substrate including a printed circuit board (PCB), a ceramic substrate, a glass substrate, a tape interconnection substrate, etc. For example, the interconnection substrate 310 may be a double-sided PCB or a multi-layer PCB.

The semiconductor chip 320 may be mounted on the interconnection substrate 310 by wire bonding or flip chip bonding. For example, a plurality of semiconductor chips 320 may be stacked in the vertical direction on the interconnection substrate 310 and electrically connected to the third lower pad 312 of the interconnection substrate 310 by bonding interconnections (WB). In an example, the semiconductor chip 320 of the upper package PKG2 may include a memory chip, and the first semiconductor chip 120 of the lower package PKG1 may include an AP chip.

The encapsulant 330 may include a material identical or similar to that of a molded layer 130 of the lower package PKG1. The upper package PKG2 may be physically and electrically connected to the lower package PKG1 by a conductive bump 315. The conductive bump 315 may include a low melting point metal, such as tin (Sn) or an alloy including tin (Sn)

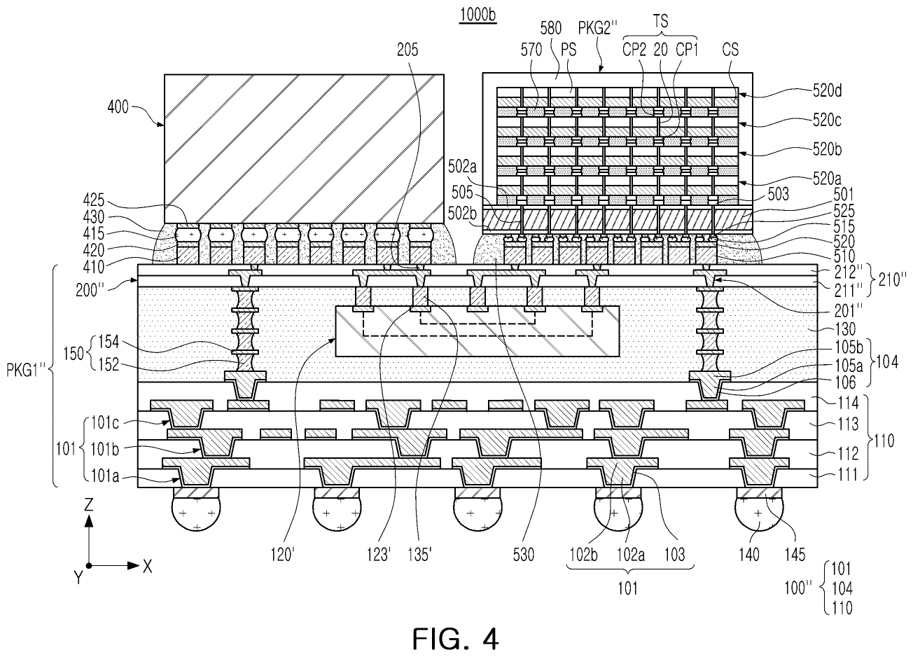

FIG. 4 is a cross-sectional view of a semiconductor package according to another embodiment of the present inventive concept.

Referring to FIG. 4, the semiconductor package 1000b may include a first semiconductor structure, e.g., a lower package PKG1″, a second semiconductor structure, e.g., a second semiconductor chip 400 disposed on the lower package PKG1″, and a third semiconductor structure, e.g., an upper package PKG2″.

The lower package PKG1″ may include a first redistribution structure 100″, a second redistribution structure 200″, connection structures 150 disposed between the first redistribution structure 100″ and the second redistribution structure 200″, and a bridge die 120′ electrically connected to the second redistribution structure 200″.

The first redistribution structure 100″ may correspond to a redistribution structure in which the second connection patterns 107 are removed from the first redistribution structure 100 of the semiconductor package 1000 of FIG. 1.

The second redistribution structure 200″ may include a second redistribution insulating layer 210″, second redistribution conductive patterns 201″ in the second redistribution insulating layer 210″, and an upper connection via 205 connected to the second redistribution conductive patterns 201″. Each of the second redistribution conductive patterns 201″ may correspond to the (2-1)-th redistribution conductive patterns 201a of the second redistribution structure 200 of FIG. 1.

The second redistribution insulating layer 210″ may include a (2-1)-th redistribution insulating layer 211″ and a (2-2)-th redistribution insulating layer 212″ on the (2-1)-th redistribution insulating layer 211″. The (2-2)-th redistribution insulating layer 211″ may be disposed on a side surface of the second redistribution via of each of the second redistribution conductive patterns 201″. The (2-2)-th redistribution insulating layer 212″ may cover a second redistribution line of each of the second redistribution conductive patterns 201″, and may be disposed on a side surface of the upper connection via 205.

The bridge die 120′ may be spaced apart from the first redistribution structure 100″ on an upper surface of the first redistribution structure 100″ in the vertical direction (Z-direction).

The bridge die 120′ may be electrically connected to the second redistribution structure 200″ through bridge connection structures 135′. The bridge die 120′ may include bridge pads 123′ provided on an upper surface of the bridge die 120′. The bridge connection structures 135′ may be disposed between the bridge pads 123′ and the second redistribution conductive patterns 201″ of the second redistribution structure 200″. In an example, the bridge die 120′ may be a semiconductor chip formed of silicon (Si). The bridge connection structures 135′ may include copper (Cu).

The connection structure 150 of the semiconductor package 1000b may be applied with the connection structures 150, 150′ and 150″ described with reference to FIGS. 1 to 2C.

The semiconductor package 1000b may further include first sub-connection structures 410 and second sub-connection structures 510 disposed on the second redistribution structure 200″, fourth upper pads 420 disposed on the first sub-connection structures 410, fifth upper pads 520 disposed on the second sub-connection structures 510, first upper connection bumps 415 disposed on the fourth upper pads 420, and second upper connection bumps 515 disposed on the fifth upper pads 520.

The second semiconductor chip 400 may be disposed on the fourth upper pads 420. The second semiconductor chip 400 may be electrically connected to the second redistribution structure 200″ of the lower package PKG1″ through the first upper connection bumps 415. The second semiconductor chip 400 may include first upper connection pads 425 disposed on a lower surface of the second semiconductor chip 400. The first upper connection bumps 415 may be disposed between the first upper connection pads 425 and the fourth upper pads 420. The second semiconductor chip 400 may be a memory chip. The memory chip may include a volatile memory chip such as a dynamic random access memory (DRAM) or a static random access memory (SRAM), or a nonvolatile memory chip such as a phase-change random access memory (PRAM), a magneto-resistive random access memory (MRAM), a ferroelectric random access memory (FeRAM), or a resistive random access memory (RRAM).

The upper package PKG2″ may include a base 501, a plurality of semiconductor chips 520a, 520b, 520c and 520d, an adhesive material layer 570, and a second molded layer 580. The upper package PKG2″ may be disposed on the fifth upper pads 520.

The base 501 may be a buffer semiconductor chip or a logic semiconductor chip. In an example, the base 501 may have a width or size greater than those of the plurality of semiconductor chips 520a, 520b, 520c and 520d. The base 501 may further include an upper protective layer 502a disposed on an upper surface of the base 501 and a lower protective layer 502b disposed on a lower surface of the base 501. The base 501 may include a through-hole electrode structure 505 penetrating the base 501, a base upper pad 503 electrically connected to the through-hole electrode structure 505 on an upper protective layer 502a, and a base lower pad 525 electrically connected to the through-hole electrode structure 505 below the lower protective layer 502b.

The upper package PKG2″ may be electrically connected to the second redistribution structure 200″ of the lower package PKG1″ through the second upper connection bumps 515.

The plurality of semiconductor chips 520a, 520b, 520c and 520d may be sequentially stacked in the vertical direction (Z-direction) on the base 501. The plurality of semiconductor chips 520a, 520b, 520c and 520d are illustrated as including four semiconductor chips, but are not limited thereto, and for example, may include four or more semiconductor chips.

In an embodiment, the plurality of semiconductor chips 520a, 520b, 520c and 520d are illustrated as having the same shape, but are not limited thereto. For example, the plurality of semiconductor chips 520a, 520b, 520c and 520d may include different types of semiconductor chips or different shapes of semiconductor chips. In an example, the plurality of semiconductor chips 520a, 520b, 520c and 520d may be memory semiconductor chips such as a DRAM.

Each of the plurality of semiconductor chips 520a, 520b, 520c and 520d may include a first chip structure CS, a second chip structure PS disposed on the first chip structure CS, and a chip connection structure TS penetrating the first chip structure CS and the second chip structure PS.

The chip connection structure TS may penetrate the first and second chip structures CS and PS in the vertical direction (Z-direction). In an example, the chip connection structure TS may include a third connection pad CP1, a fourth connection pad CP2 vertically overlapping the third connection pad CP1, and an intermediate connection structure 20 disposed between the third connection pad CP1 and the fourth connection pad CP2. In an example, the third and fourth connection pads CP1 and CP2 may be input/output pads. In an example, the third connection pad CP1 may be disposed adjacent to a lower surface of the first chip structure CS, and the fourth connection pad CP2 may be disposed adjacent to an upper surface of the second chip structure PS. The adjacent plurality of semiconductor chips 520a, 520b, 520c and 520d may be electrically connected to each other through the chip connection structure TS.

In an embodiment, the adhesive material layer 570 may surround a space between the first semiconductor chip 520a and the base 501, a space between the plurality of semiconductor chips 520a, 520b, 520c and 520d, and side surfaces of the plurality of semiconductor chips 520a, 520b, 520c and 520d. In an example, the adhesive material layer 570 may include an epoxy material. For example, the adhesive material layer 570 may be a non-conductive film (NCF), but the embodiment is not limited to such a material.

In an embodiment, the second molded layer 580 may be disposed to cover the plurality of semiconductor chips 520a, 520b, 520c and 520d and the adhesive material layer 570 to protect the plurality of semiconductor chips 520a, 520b, 520c and 520d and the adhesive material layer 570 from an external environment. In an example, the second molded layer 580 may include an insulating material including a resin material such as an epoxy molding compound (EMC).

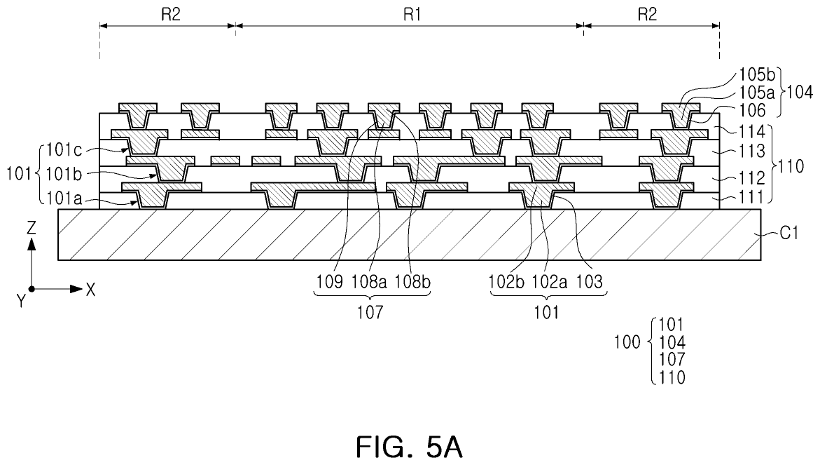

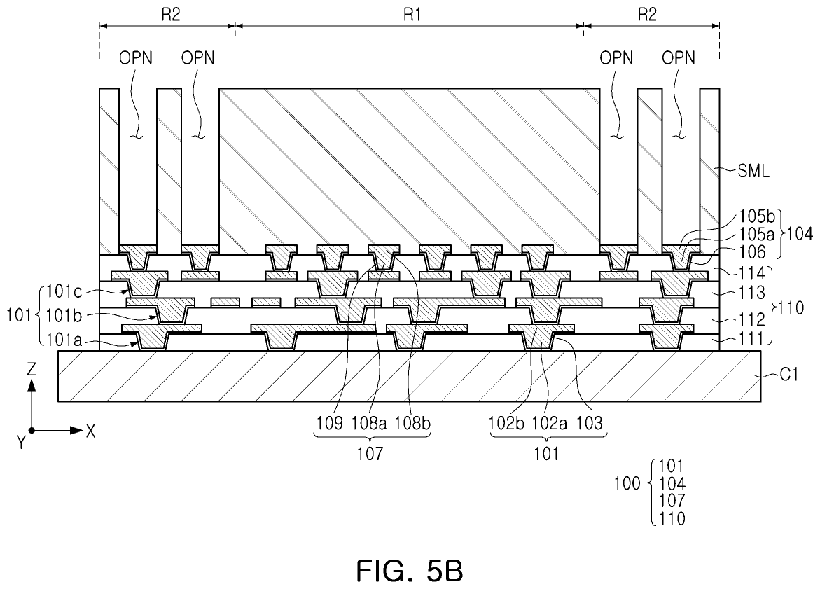

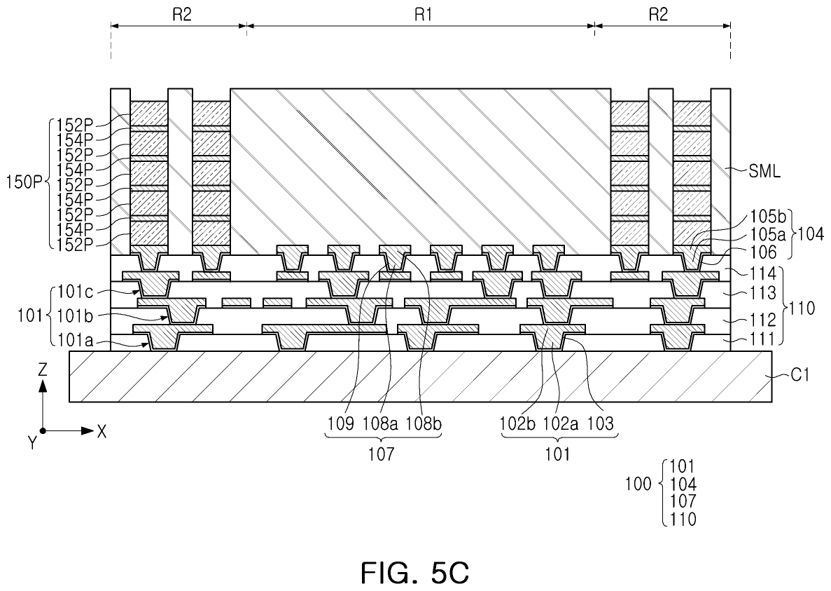

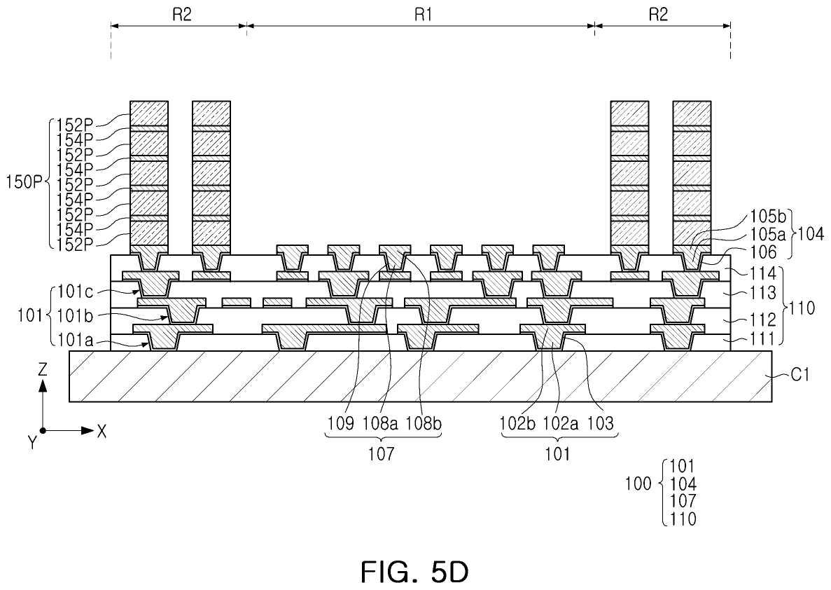

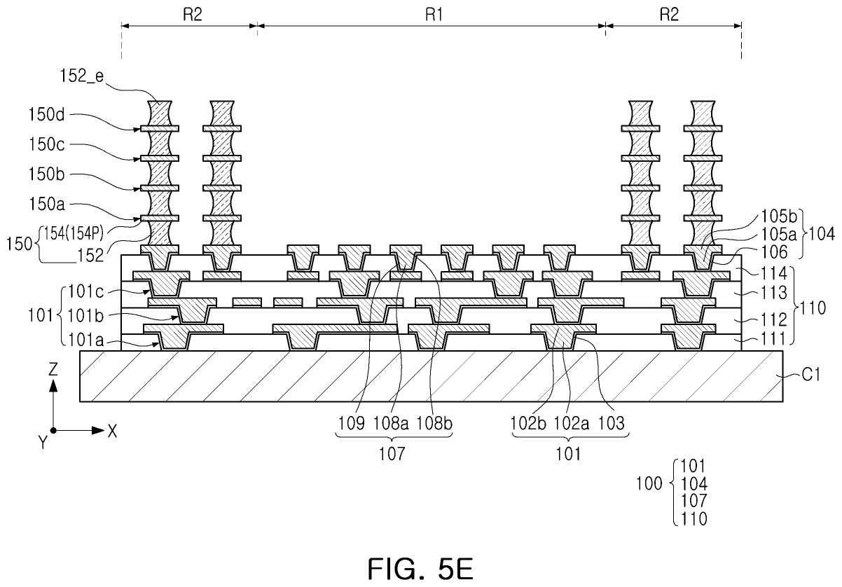

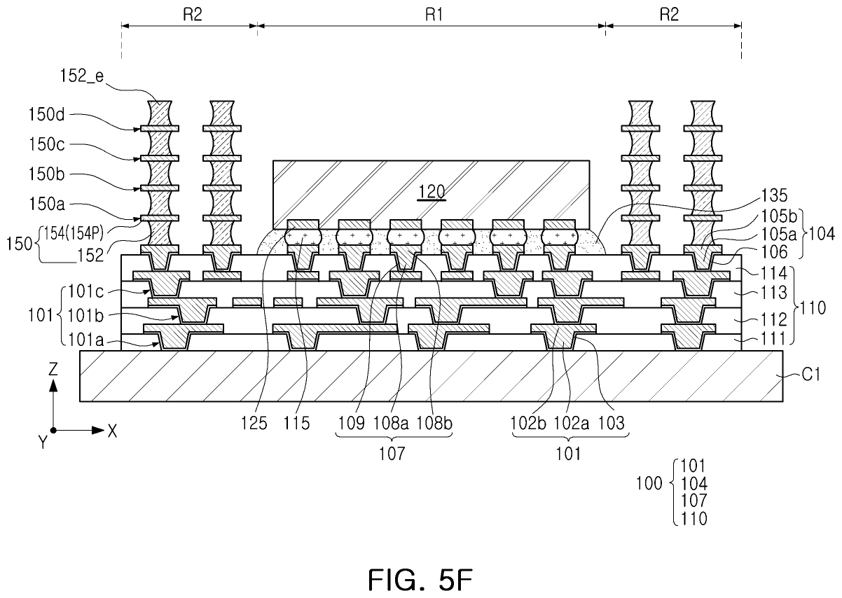

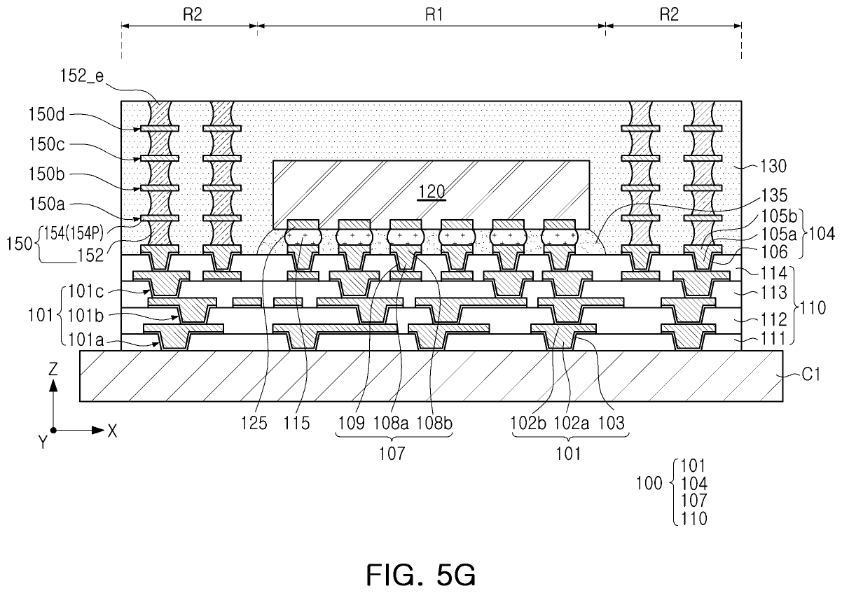

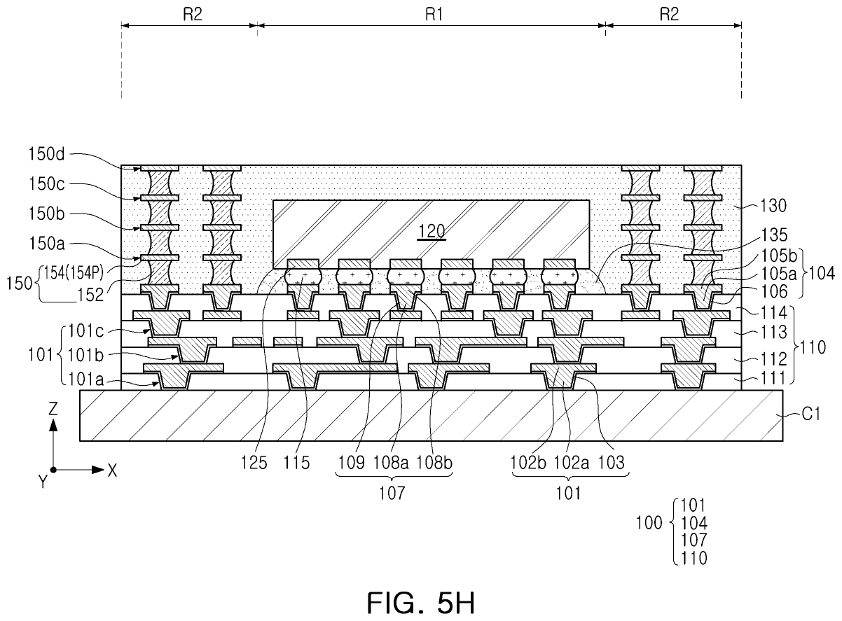

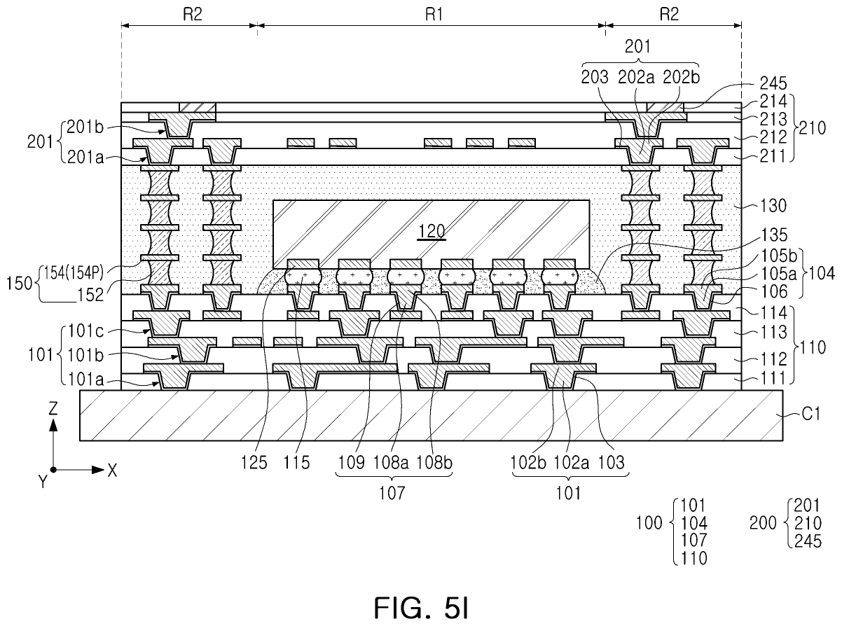

FIGS. 5A to 5I are drawings illustrating a method of manufacturing a semiconductor package according to an embodiment of the present inventive concept. Referring to FIGS. 5A to 5I, a method of manufacturing the semiconductor package 1000 of FIG. 1 will be described.

Referring to FIGS. 5A to 5I, the method of manufacturing a semiconductor package 1000 may include an operation of forming a first redistribution structure 100 on a carrier substrate C1 (see FIG. 5A), an operation of forming a sacrificial molded structure SML on the first redistribution structure 100, an operation of forming openings OPN penetrating the sacrificial molded structure SML to expose upper surfaces of first connection patterns 104 of the first redistribution structure 100 (see FIG. 5B), an operation of forming connection structures 150P in the openings OPN (see FIG. 5C), an operation of selectively removing portions of side surface of first conductive patterns 152P of the connection structures 150P (see FIG. 5E), an operation of forming a first semiconductor chip 120 on the first redistribution structure 100 (see FIG. 5F), an operation of covering a side surface and an upper surface of the first semiconductor chip 120, and forming a first molded layer 130 on the side surface of the connection structure 150 (see FIG. 5G), and an operation of forming a second redistribution structure 200 on the connection structures 150 (see FIG. 5I).

Referring to FIG. 5A, the first redistribution structure 100 including first redistribution conductive patterns 101, first connection patterns 104 connected to the first redistribution conductive patterns 101, and second connection patterns 107 may be formed on a carrier substrate C1.

The carrier substrate C1 may be a temporary support including a silver glass wafer, a curable resin layer, etc. The operation of forming the first redistribution conductive patterns 101 may include an operation of forming (1-1)-th redistribution insulating layers 111, forming via holes, and then conformally forming a seed layer along a surface of the (1-1)-th redistribution insulating layer 111, an operation of forming a photoresist pattern (not shown) exposing a region for forming a first redistribution line 102b of the first redistribution conductive pattern (101), and then forming a conductive layer, and an operation of subsequently removing the photoresist pattern by an ashing process. The first redistribution conductive patterns 101 may be formed by a plating process using the first seed layer 103 as a seed. The first seed layer 103 may be a double layer including titanium (Ti) and copper (Cu). The conductive layer may include copper (Cu) or an alloy thereof. The first connection patterns 104 and the second connection patterns 107 may be formed in the same manner as the first redistribution conductive patterns 101. The first connection patterns 104 may be formed in a second region R2 overlapping with connection structures 150 (e.g., the connection structures 150 of FIG. 1) described below, and the second connection patterns 107 may be formed in a first region R1 overlapping with a first semiconductor chip (e.g., the first semiconductor chip 120 of FIG. 1) described below.

Referring to FIG. 5B, the sacrificial molded structure SML may be formed on an upper surface of the first redistribution structure 100, and the openings OPN may be formed so that upper surfaces of the first connection pads 105b of the first connection patterns 104 are exposed. In an example, the sacrificial molded structure SML may include a photosensitive material. The sacrificial molded structure SML may include a photoresist pattern which is easily dissolved by a developer. The openings OPN may define a region in which the connection structures (e.g., the connection structure (150) of FIG. 1) described below are formed.

Referring to FIG. 5C, the connection structures 150P may be formed on an upper surface of the first connection pads 105b so that the first conductive patterns 152P and second conductive patterns 154P are alternately disposed. The connection structure 150P in which the first conductive patterns 152P and the second conductive patterns 154P are alternately disposed may be formed by repeatedly performing a process in which a seed layer (not shown) is formed and then the first conductive pattern 152P and the second conductive pattern 154P are sequentially formed on the seed layer by a plating process. The seed layers may include a first seed layer including titanium (Ti) and a second seed layer including copper (Cu) on the first seed layer. The first conductive pattern 152P may include copper (Cu), and the second conductive pattern 154P may include nickel (Ni). In this case, an interface between the first conductive pattern 152P and the second seed layer of the seed layers may be unclear. That is, the first conductive pattern 152P may be formed on an upper surface of the first seed layer. The second conductive pattern 154P may be formed after the first conductive pattern 152P is formed, using the first conductive pattern 152P as a seed layer. In an example, the first conductive pattern 152P and the second conductive pattern 154P may be formed by a plating process, and may be formed by performing an in-situ process. A height of each of the first conductive patterns 152P in the vertical direction (Z-direction) may be formed higher than a height of each of the second conductive patterns 154P in the vertical direction (Z-direction).

The first conductive pattern 152P may be formed on a lowermost end of the connection structure 150P, and the first conductive pattern 152P or the second conductive pattern 154P may be formed on an uppermost end of the connection structure 150P. FIG. 5D illustrates an embodiment in which the first conductive pattern 152P is formed on the uppermost end of the connection structure (150P) in the present manufacturing process.

Referring to FIG. 5D, the sacrificial molded structure SML may be removed to exposed the connection structures 150P.

Referring to FIG. 5E, portions of side surfaces of the first conductive patterns 152P of the connection structure 150P may be selectively removed to form the first conductive patterns 152. The portions of the side surfaces of the first conductive patterns 152P may be removed by exposing the connection structure 150P to an etchant. The etchant may be an etchant having a relatively high etching selectivity with respect to the second conductive patterns 154P. For example, the etchant may include copper ammonium chloride (Cu(NH₃)Cl₂), ammonia (NH₃), ammonium chloride (NH₄Cl), diluted phosphoric acid (H₃PO₄), hydrogen peroxide, or the like. In an example, the side surfaces of the first conductive patterns 152P may be removed by an isotropic etching process, thereby forming the first conductive pattern 152 having a side surface with a concave curved surface.

As the portions of the side surfaces of the first conductive patterns 152P are removed while the second conductive patterns 154P are maintained, a side surface of the second conductive pattern 154 may be formed to protrude from the side surface of the first conductive pattern 152 in a horizontal direction.

As the portions of the side surfaces of the first conductive patterns 152P are removed, a plurality of conductive pattern structures 150a, 150b, 150c and 150d each including the first conductive pattern 152 and the second conductive pattern 154 formed on the first conductive pattern 152 may be formed. A first dummy conductive pattern 152_e may be formed on the plurality of conductive pattern structures 150a, 150b, 150c and 150d.

Referring to FIG. 5F, a first semiconductor chip 120 connected to the first redistribution structure 100 may be formed. The first semiconductor chip 120 may be formed to overlap the second connection patterns 107 in a vertical direction (Z-direction), and may be electrically connected to the first redistribution structure 100 through intermediate connection bumps 115. The first semiconductor chip 120 may be spaced apart from the connection structures 150 in a horizontal direction.

After forming the first semiconductor chip 120, a first underfill material layer 135 surrounding the intermediate connection bumps 115 between the first semiconductor chip 120 and the first redistribution structure 100 may be formed.

Referring to FIG. 5G, the first semiconductor chip 120 may be encapsulated, and a first molded layer 130 may be formed on side surfaces of the connection structures 150 and a side surface of the first dummy conductive pattern 152_e. The first molded layer 130 may be formed by applying an insulating material on the connection structures 150, the first dummy conductive pattern 152_e, and the first semiconductor chip 120, and then curing the insulating material.

Referring to FIG. 5H, a grinding process or a chemical mechanical polishing (CMP) process may be performed on an upper surface of the first molded layer 130. The grinding process or chemical mechanical polishing (CMP) process may be performed until an upper surface of the second conductive pattern 154 of the fourth conductive pattern structure 150d formed on an uppermost end of the plurality of conductive pattern structures 150a, 150b, 150c and 150d of the connection structure 150 is exposed. Accordingly, the first dummy conductive pattern 152_e may be removed. The upper surface of the second conductive pattern 154 of the fourth conductive pattern structure 150d may be exposed from the first molded layer 130.

Referring to FIG. 5I, the second redistribution structure 200 may be formed on the connection structures 150. A second redistribution conductive pattern 201 of the second redistribution structure 200 may be formed to be in contact with the upper surface of the second conductive pattern 154 of the fourth conductive pattern structure 150d.

Next, referring to FIG. 1 together, after removing the carrier substrate C1, the semiconductor package 1000 of FIG. 1 may be manufactured by sequentially forming lower pads 145 and lower connection bumps 140 on a lower surface of the first redistribution structure 100.

A semiconductor package according to embodiments of the present inventive concept may include connection structures connecting redistribution structures, each of the connection structures may include first conductive patterns and second conductive patterns alternately disposed with the first conductive patterns, and each of the first conductive patterns may have a side surface disposed inwardly of a side surface of each of the second conductive patterns. Accordingly, since the side surface of each of the second conductive patterns has a structure protruding from the side surface of each of the first conductive patterns, generation and diffusion of an oxidation layer between the first conductive pattern and a molded layer may be improved, thereby providing a semiconductor package with improved reliability.

According to an aspect of the present inventive concept, a method of manufacturing a semiconductor package may comprise: forming a first redistribution structure comprising first redistribution conductive patterns on a carrier substrate; forming a connection structure comprising first conductive patterns and second conductive patterns alternately disposed with the first conductive patterns on the first redistribution structure; removing portions of side surfaces of the first conductive patterns in a horizontal direction so that the side surfaces of the first conductive patterns are formed inwardly of side surfaces of the second conductive patterns; forming a first semiconductor chip on the first redistribution structure; forming a first molded layer covering the side surface and the upper surface of the first semiconductor chip on the side surface of the connection structure; and forming a second redistribution structure comprising second redistribution conductive patterns on the connection structure.

According to an embodiment, the method of manufacturing the semiconductor package may further comprise: forming a molded structure on the first redistribution structure; forming openings penetrating the molded structure to expose at least a portion of an upper surface of the first redistribution structure; forming the connection structure in the openings; and removing the molded structure.

According to an embodiment, removing the portions of the side surfaces of the first conductive patterns in the horizontal direction may comprise selectively etching the side surfaces of the first conductive patterns using an etchant.

According to an embodiment, forming each of the first conductive patterns may comprise forming a seed layer, and forming a first conductive layer on the seed layer, and forming each of the second conductive patterns may comprise forming a second conductive layer on the first conductive layer of each of the first conductive patterns.

According to an embodiment, the seed layer may comprise a first seed layer and a second seed layer formed on the first seed layer, and the first seed layer may comprise titanium (Ti), and the second seed layer may include copper (Cu).

According to an embodiment, the first conductive layer may include copper (Cu), and the second conductive layer may include nickel (Ni).

According to an embodiment, the method of manufacturing the semiconductor package may further comprise flattening an upper surface of the molded layer and upper surfaces of the connection structures so that an upper surface of a second upper conductive pattern formed on an uppermost end of the second conductive patterns of the connection structure is exposed.

According to an embodiment, forming the second redistribution structure may comprise forming a second redistribution insulating layer on the molded layer and the connection structure, and including each of the second redistribution conductive patterns including a second redistribution via penetrating the second redistribution insulating layer to be in contact with the second upper conductive pattern, and a second redistribution line extending from the second redistribution via on the second redistribution via.

According to an embodiment, the second redistribution insulating layer may comprise a photoimageable dielectric (PID) insulating material.

According to an embodiment, forming the first redistribution structure may comprise forming a first redistribution insulating layer on the carrier substrate, and including a first redistribution via penetrating the first redistribution insulating layer and a first redistribution pad extending from the first redistribution via on the first redistribution via, wherein a first lower conductive pattern formed on a lowermost end of the first conductive patterns of the connection structure may in contact with an upper surface of the first redistribution pad.

However, the effects of the present inventive concept are not limited to the effects described above, and may be expanded in various ways without departing from the spirit and scope of the present inventive concept.

While example embodiments have been shown and described above, it will be apparent to those skilled in the art that modifications and variations could be made without departing from the scope of the present inventive concept as defined by the appended claims.

What is claimed is:

1. A semiconductor package, comprising:
a first redistribution structure comprising first redistribution conductive patterns;
a first semiconductor chip disposed on the first redistribution structure, and electrically connected to the first redistribution structure;
a connection structure disposed on the first redistribution structure spaced apart from the first semiconductor chip in a horizontal direction, and electrically connected to the first redistribution structure; and
a second redistribution structure disposed on the connection structure and comprising second redistribution conductive patterns,
wherein the connection structure comprises:
first conductive patterns comprising a first conductive material; and
second conductive patterns comprising a second conductive material, different from the first conductive material, and alternately disposed with the first conductive patterns in a vertical direction intersecting the horizontal direction, and
each of the second conductive patterns has a side surface protruding in the horizontal direction from a side surface of the respective first conductive pattern.

2. The semiconductor package of claim 1, wherein a first lower conductive pattern disposed on a lowermost end of the first conductive patterns is in contact with an upper surface of the first redistribution structure.

3. The semiconductor package of claim 1, wherein a second upper conductive pattern disposed on an uppermost end of the second conductive patterns is in contact with a lower surface of the second redistribution structure.

4. The semiconductor package according to claim 1, wherein, each of the first conductive patterns has a first height in the vertical direction, and
each of the second conductive patterns has a second height, less than the first height, in the vertical direction.

5. The semiconductor package of claim 4, wherein, the first height is 3 times or more and 4 times or less of the second height.

6. The semiconductor package of claim 1, wherein a side surface of each of the first conductive patterns has a concave curved surface.

7. The semiconductor package of claim 1, wherein each of the first conductive patterns comprises a first metal layer and a second metal layer on the first metal layer,
each of the second conductive patterns comprises a third metal layer on the second metal layer of the respective first conductive pattern, and
the first metal layer, the second metal layer, and the third metal layer respectively comprise metal materials different from each other.

8. The semiconductor package of claim 7, wherein the first metal layer comprises titanium (Ti),
the second metal layer comprises copper (Cu), and
the third metal layer comprises nickel (Ni).

9. The semiconductor package of claim 1, wherein a height of each of the second conductive patterns in the vertical direction is about 3 μm or less.

10. The semiconductor package of claim 1, wherein a maximum width of each of the second conductive patterns in the horizontal direction is greater than a maximum width of the respective first conductive pattern in the horizontal direction.

11. The semiconductor package of claim 1, wherein a side surface of each of the second conductive patterns protrudes from a side surface of the respective first conductive patterns by 200 nm or more and 300 nm or less in the horizontal direction.

12. The semiconductor package of claim 1, wherein a first upper conductive pattern disposed on an uppermost end of the first conductive patterns is in contact with a lower surface of the second redistribution structure.

13. The semiconductor package of claim 1, wherein a height in the vertical direction of a first lower conductive pattern disposed on a lowermost end of the first conductive patterns is greater than a height in the vertical direction of a first uppermost conductive pattern disposed an uppermost end of the first conductive patterns.

14. A semiconductor package, comprising:
a first redistribution structure comprising first redistribution conductive patterns;
a connection structure disposed on the first redistribution structure, and electrically connected to the first redistribution structure;
a first molded layer disposed on a side surface of the connection structure; and
a second redistribution structure disposed on the connection structure and the first molded layer, and comprising second redistribution conductive patterns,
wherein the connection structure comprises a plurality of conductive pattern structures stacked in a vertical direction, and
each of the plurality of conductive patterns comprises:
a first conductive pattern comprising a first conductive material; and
a second conductive pattern disposed on the first conductive pattern, and comprising a second conductive material, different from the first conductive material, and
each of the first conductive patterns has a side surface disposed inwardly of a side surface of the respective second conductive pattern.

15. The semiconductor package of claim 14, wherein the plurality of conductive pattern structures comprise a first conductive pattern structure, a second conductive pattern structure on the first conductive pattern structure, and a third conductive pattern structure on the second conductive pattern structure.

16. The semiconductor package of claim 14, wherein a lower surface of the second conductive pattern comprises a first region vertically overlapping the first conductive pattern in the vertical direction and a second region exposed from the first conductive pattern and being in contact with the first molded layer.

17. The semiconductor package of claim 14, wherein the first redistribution structure further comprises a first redistribution insulating layer on side surfaces of the first redistribution conductive patterns,
the second redistribution structure further comprises a second redistribution insulating layer on side surfaces of the second redistribution conductive patterns, and
the first redistribution insulating layer and the second redistribution insulating layer comprise a photoimageable dielectric (PID) insulating material.

18. The semiconductor package of claim 14, further comprising:
a first semiconductor chip spaced apart from the first redistribution structure in the vertical direction, and electrically connected to the second redistribution structure;
bridge pads disposed on an upper surface of the first semiconductor chip; and
bridge connection structures disposed on the bridge pads,
wherein the first molded layer is disposed on side surfaces of the bridge connection structures, and
the second redistribution structure is disposed on the bridge connection structures.

19. The semiconductor package of claim 14, further comprising:
a first semiconductor structure disposed on the second redistribution structure; and
a second semiconductor structure disposed on the second redistribution structure, and spaced apart from the first semiconductor structure in a horizontal direction,
wherein the first semiconductor structure comprises a interconnection substrate, a semiconductor die vertically stacked on the interconnection substrate, and a second molded layer covering the semiconductor die.

20. A semiconductor package, comprising:
a lower package;
conductive bumps disposed on the lower package; and
an upper package disposed on the conductive bumps,
wherein the lower package comprises:
a first redistribution structure comprising first redistribution conductive patterns, and having a lower surface on which lower pads connected to the first redistribution conductive patterns are disposed;
lower pads disposed on the lower surface of the first redistribution structure;
lower connection bumps disposed below the lower pads;
a first semiconductor chip disposed on the first redistribution structure, and electrically connected to the first redistribution structure;
a connection structure disposed on the first redistribution structure spaced apart from the first semiconductor chip in a horizontal direction, and electrically connected to the first redistribution structure; and
a second redistribution structure disposed on the connection structure, and comprising second redistribution conductive patterns, and
the connection structure comprises:
first conductive patterns comprising a first conductive material; and
second conductive patterns comprising a second conductive material, different from the first conductive material, and alternately disposed with the first conductive patterns in a vertical direction intersecting the horizontal direction, and
each of the second conductive patterns has a side surface protruding in the horizontal direction from a side surface of the respective first conductive pattern.
